(19) United States
(12) Patent Application Publication
(10) Pub. No.: US 2015/0355297 A1
(43) Pub. Date: Dec. 10, 2015

(54) SYSTEM AND METHOD FOR DECOUPLING MAGENTIC RESONANCE IMAGING RADIO FREQUENCY COILS WITH A MODULAR MAGNETIC WALL

(71) Applicant: Ravi MENON, London (CA)

(72) Inventors: Ravi Menon, London (CA); Mohamed Aboukhousa, London (CA)

(21) Appl. No.: 14/759,816

(22) PCT Filed: Jan. 11, 2013
(86) PCT No.: PCT/US2013/021202

§ 371 Date: Jul. 8, 2015

(51) Int. Cl. G01R 33/36; G01R 33/422

(52) U.S. Cl. CPC G01R 33/365; G01R 33/422

(57) ABSTRACT

A system and method for decoupling radio frequency (“RF”} coils arranged in proximity to each other is provided. The decoupling is achieved using a magnetic wall that includes resonators arranged on an electrically insulating substrate. The magnetic wall is placed between the RF coils. When an electromagnetic field produced by one of the RF coils is incident on the magnetic wall, the magnetic wall acts to cancel the incident electromagnetic field by attenuating or redirecting the incident field. The magnetic wall is modular, and an array of such magnetic walls can be used to enclose individual RF coil elements, or sub-arrays of two or more RF coil elements.

### BACKGROUND OF THE INVENTION

The field of the invention is systems and methods for magnetic resonance imaging (“MRI”) and magnetic resonance spectroscopy (“MRS”). More particularly, the invention relates to systems and methods for decoupling radio frequency (“RF”) coils for MRI and MRS.

In MRI and MRS, the substance under examination, e.g., human tissue, is subject to a strong and uniform static magnetic field, B₀, oriented along a direction of a Cartesian coordinate system, typically the z-axis. The nuclear spins of the substance, each with finite magnetic moment, align themselves along the direction of the static magnetic field, resulting in a collective magnetization vector aligned along the same direction. RF pulses with proper frequency (i.e., the Larmor frequency of the nuclear spin species to be excited) are applied in the plane transverse (e.g., the x-y plane) to the static magnetic field, B₀, to produce a uniform RF field, B₁, over the field-of-view (“FOV”). This uniform excitation field “tips” the magnetization vector off the z-axis towards the transverse, x-y plane.

When the RF excitation field is turned-off, the nuclear spins precess about the z-axis at their characteristic Larmor frequency before they eventually align again along the z-axis. During precession, the finite transverse magnetization vector rotates in the x-y plane and produces weak magnetic resonance RF signals that can be detected using RF probes or “coils”, i.e., by the virtue of Faraday induction. The magnitude and temporal/phase characteristics of the detected RF signals reveal the sought information about the substance under examination. In imaging, magnetic field gradients are applied in the x-, y-, and z-directions to provide three-dimensional localization whereby the nuclei are excited and magnetic resonance RF signals are detected within the sequence of applying these gradients. Using the detected signals in concert with the applied gradients, magnetic resonance images are produced using well-established reconstruction techniques.

In typical MRI systems, a “volume” or “whole-body” RF coil, e.g., a “birdcage” coil, TEM resonator, and so on, is used to provide the uniform RF excitation field over the FOV, and an array of surface receive coils are used for simultaneous and localized detection of the magnetic resonance signals generated from specific regions, e.g., from the subject's head. After the RF excitation pulse is turned off, the magnetic resonance RF signal generated due to the precessing nuclear spins are received simultaneously by the array of surface coils arranged in close proximity around the object or anatomy to be imaged. In general, MRI RF coil arrays include tuned/resonant loops or transmission line elements arranged in one-, two-, or three-dimensional configurations around the object or anatomy to be imaged or combination of both. These elements are designed to be resonant at the Larmor frequency of the excited nuclei. The coil array elements are typically matched to the rest of the RF chain connected to them, e.g., 50 Ohm. The signals detected by the receive array elements are amplified by a low noise amplifier (“LNA”)/preamplifier before they are processed in the receiver chains (e.g., mixers, filters, digital detection, etc). Typically, receive arrays with high channels counts are employed to extend the receive FOV, e.g., 32 channel receive coil arrays are quite common in clinical MRI systems.

In MRI, it is desirable to have uniform/homogenous RF transmission and reception over the spatial extent of the FOV. The transmit volume coil can be used for reception as well as transmission when the coil is operated in a transmit-receive mode with a proper transmit/receive (“T/R”) switch. Although volume coils provide high RF field homogeneity over a large FOV, the overall receive signal-to-noise ratio (“SNR”) is low due to the collective noise picked up from that FOV. While dedicated surface coils placed close to the subject under examination were proposed to enhance region-specific SNR, they suffer from limited receive FOV. Arrays of these surface receive coils as described above were originally proposed to extend the receive FOV while preserving the high local SNR offered by the individual surface coils. In addition to the SNR improvements compared to volume coils, the utility of receive surface coil arrays has significantly expanded since the emergence of the viable parallel imaging and fast MRI techniques such as SENSE and SMASH.

With the recent advent of high and ultra high-field MRI and MRS, e.g., 3 Tesla B₀ strength and greater, driven by the potential increase in SNR, contrast, and resolution, the utility of the conventional volume coils and their ability to produce uniform RF field excitation have been significantly undermined. This is due to the dominant wave behavior at these high field strengths, e.g., wave interaction with the tissues under examination results in standing waves and consequently field non-uniformities. Furthermore, due to their intrinsically large FOV and low efficiency at high fields, volume coils require relatively high RF power to achieve the desired excitation. This combined with their excitation non-uniformity can potentially create “hot” spots within the human subject. These hot spots bring about serious RF power deposition and patient safety concerns when using such volume coils, i.e., exceeding the local specific absorption rate (“SAR”) regulatory limit. To address these challenges, the use of arrays of transmit coils, i.e., transmit arrays, has been proposed to control electromagnetic fields distribution and SAR within the subject under examination.

In general, and similar to receive arrays, transmit arrays are constructed from tuned loop or transmission line coil elements arranged around the region-of-interest and driven independently with dedicated RF transmit chains/channels. The RF excitation and SAR distribution can be controlled to synthesize uniform excitation and eliminate hot spots by controlling the phase and magnitude on each transmit channel, i.e., the so called “RF shimming.” Similar to receive arrays, the utility of transmit arrays has expanded since the emergence of transmit parallel imaging, i.e. transmit SENSE. It is also noted that transmit arrays can be used with dedicated receive only arrays or configured as transmit-receive arrays employing T/R switches to enable transmission and detection using the same array elements.

The operational objectives of the RF coil array can be achieved efficiently only if the array elements are mutually decoupled, i.e., their signals and field distributions are independent. In essence, to fully benefit from parallel imaging techniques it is imperative that the excitation fields of the coil array elements, i.e., their sensitivities, be mutually orthogonal in the FOV and that their receive noise be uncorrelated. Achieving these ends constitutes one of the major challenges in designing robust MRI transmit, receive, and transceive coil arrays.

In MRI coil arrays, the coil elements are placed in very close proximity to each other, typically with inter-spacing of less that five percent of the operating wavelength. In some instances, coil elements are also overlapped by about 10-15 percent to reduce mutual inductance between nearest neighbor coils, but coil elements beyond nearest neighbor coils will still couple. Consequently, strong mutual coupling presents intrinsically among the coil elements (undesired transfer of energy from a one coil to another). Such mutual coupling results in undesired interference between the array elements to the extent that their noise becomes highly correlated and their spatial sensitivities become mutually dependent. This undesired coupling impacts the overall MRI coil performance in many aspects. Mutual coupling makes tuning and matching the array elements rather challenging, i.e., it results in mode splitting. Furthermore, such coupling significantly undermines the ability to independently control the phase and magnitude of the RF signal feeding each array element, thereby limiting RF shimming as well as parallel imaging techniques. In receive arrays, mutual coupling not only limits the attainable acceleration factors but also results in high noise correlation among the receive channels. This in turn reduces the overall signal-to-noise ratio and consequently degrades the image quality.

As noted above, various types of coil elements can be used to construct RF coil arrays for use in MRI. Examples of these coil elements include loops (square, circular, etc), transmission lines, and so on. By way of example, a loop coil element suitable for use in an RF coil array for MRI is shown in FIG. 1. Such coil elements 100 are typically made of conductive—e.g., copper—traces or wires 102 and are designed to be resonant at the Larmor frequency of the nuclei of interest for imaging, such as hydrogen-1 (proton), sodium-23, phosphorus-31, oxygen-17, and so on. To this end, appropriate capacitance is added to the structure of these elements 100. To reduce radiation losses, distributed capacitance is added along the length of the coil element 100. The coil elements 100 are typically matched to the rest of the RF chain connected to them through the feeding line 104. The feeding line 104 can be any transmission line (coax, waveguide, microstrip, etc.) utilized to transmit the RF excitation to the coil element and/or to receive a magnetic resonance signal from the coil element. A balanced-to-unbalanced transformer (“balun”) 106 is usually used at the input of the coil element 100.

The coil element 100 can be matched and tuned using any method, including known methods such as an L-network composed of series and shunt capacitors at the inputs. The series of capacitors is typically distributed around the coil element as shown in FIG. 1. Referring to FIG. 1, C₁ and C₂ are distributed capacitance. The coil element 100 can be matched by varying an input capacitor, C_{M}, and can be tuned to the desired frequency by varying a tuning capacitor, C_{T}. For instance, a coil element 100 can be matched and tuned to operate for proton imaging at 7T in order to result in a typical reflection coefficient, S₁₁, response for an isolated resonant element, as shown in FIG. 2. The shape and size of the coil element 100, placement of the balun 106, number of capacitors along with their designations, and the feeding line 104 are arbitrary and can be changed. Multiple feeding lines operating at the same or different resonance frequencies could be used as well.

Commonly, RF coil arrays include a number of coil elements paced near one another and arranged around the object to be imaged. FIG. 3A illustrates an example of an RF coil array 300 including two coil elements 302, 304 that are spaced apart by an interspacing distance, S. Mutual coupling between these coil elements 302, 304 is manifested by the fact that a current flowing in one coil element 302 induces a current in the other, neighboring coil element 304 and vise versa. Without loss of generality, coil elements can also be overlapped, such that the distance, s, indicates the extent to which the coils are overlapped. FIG. 3B illustrates an example of an RF coil array 300 including two coil elements 302, 304 that are arbitrarily overlapped by a distance, s. Mutual coupling between coil elements 302 and 304 occurs because a current flowing in one coil element 302 induces a current in the neighboring coil element 304, and vise versa.

The reflection coefficient, S₁₁, measured at the input of coil element 302 is illustrated in FIG. 4. As seen in FIG. 4, the reflection coefficient response shows two distinct nulls 402, 404 at mode frequencies f₁ and f₂, respectively, that correspond to the typical “mode-splitting” due to the fact that the coil elements 302, 304 are tightly coupled. The frequencies f₁ and f₂ are typically referred to as the eigenfrequencies of the coupled resonators. It is important to realize that the area between tightly coupled coil elements 302, 304 can be thought of as a distributed resonator with resonance frequency, f₂. Equivalently, the coupled magnetic field component in-between coupled coil elements 302, 304 can be thought of a secondary induced magnetic field, B_{c}, oscillating at a frequency, f₂. This higher eigenfrequency, f₂, may be referred to as the coupled mode frequency. Therefore, a method that suppresses the magnetic field component, B_{c}, that is responsible for the mutual coupling in this region can eliminate the mutual coupling between the coil elements 302, 304. When the coil elements 302, 304 partially overlap, the same principles apply. In this case, the region where the coupled mode frequency, f₂, can be measured is in the area of overlap between the two coil elements 302, 304.

FIG. 5 illustrates the electromagnetic coupling between the coil elements by showing the magnetic flux lines 308 linking both coil circuits, when one coil 302 is driven by a current and the other coil 304 is properly terminated. Due to the magnetic flux linkage, a current is induced in coil element 304 and, consequently, undesired interfering voltage is developed across the terminal of coil 304. This type of coupling is generally referred to as “inductive” or “magnetic” coupling. It is remarked that, depending on the coil element type and array configuration, in addition to the magnetic fields depicted in FIG. 5 the RF electric field can contribute to the mutual coupling and give rise to the so-called “capacitive coupling.” Note that the magnetic coupling results in f₂ being greater than f₁.

FIG. 6 shows a pictorial curve 602 of the relative magnitude of the vector magnetic field density, |B| as a function of position along the line 306 linking both coil elements 302, 304. The direction of the coupled component of the magnetic field vector, B_{c}, in the area between the two coil elements 302, 304 is annotated in FIG. 6 by arrow 604. For the particular loop pair arrangement shown in FIG. 3, this magnetic field component in-between the coil elements 302, 304 is responsible for establishing the mutual coupling.

Recognizing the problem of mutual coupling in MRI coil arrays, various techniques have been developed to reduce its effect; each with its own merits and disadvantages. Some of these techniques were tailored for transmit arrays, some for receive arrays, and some for transceive arrays.

One of the most prominent methods to decouple elements in MRI receive arrays is loop overlapping in conjunction with low/high impedance preamplifiers or LNAs. Recognizing that coupling between loops is dominantly magnetic (inductive) in nature, this method applies specifically to loop type RF coils whereby adjacent loop elements are slightly over-lapped to cancel the mutual flux linking the coupled elements. The next neighbor elements (i.e., non-adjacent) are decoupled by reducing the loop input port currents via loading that port with high impedance; effectively converting the loop to a voltage source. To this end, a low-input impedance preamplifier/LNA (e.g., <2 Ohm) is used and its impedance is transformed to a high impedance, ideally open, at the loop terminals. High-input impedance preamplifiers can be used if placed directly at the loop terminals (or within multiple of half-wavelength from that terminal). Various implementations of this decoupling method are disclosed in U.S. Pat. Nos. 4,825,162; 5,198,768; 6,323,648; and 7,560,934.

Unfortunately, this loop overlapping method works only for receive arrays made of loops and when low/high-input impedance preamplifiers/LNA can be utilized. The limitations of this method include that overlapping the coil array elements results in highly overlapped field sensitivities, which potentially impairs parallel imaging performance by reducing the potential acceleration factor (i.e., overlapping results in non-orthogonal field patterns). Furthermore, overlapping array elements places geometrical restriction on the array coil construction, e.g., coils with detached parts for convenient patient/subject access cannot be readily used. Additionally, loading the coil input with high impedance reduces the magnitude of the signal of interest as well as coupled signal. This, in turn, reduces the coil sensitivity to detect weak magnetic resonance signals, e.g., signals originating from places relatively far from the coil element. Fundamentally, overlapping loop coil elements reduces the magnetic coupling only and not coupling due to the electric field, as may arise in high-field coils. Finally, developing stable low/high-input impedance preamplifier for array applications is not trivial in many cases. Due to these limitations, the following methods were suggested.

Connecting capacitive and inductive networks directly between coil array elements to reduce mutual coupling have been disclosed in many variations. Inductive decoupling techniques such as the one disclosed in U.S. Pat. No. 5,489,847 is based on using coupled inductors arranged such that their mutual inductance counteracts the inductance between the coil elements used for imaging. Capacitive decoupling networks use capacitors instead of coupled inductors to counteract the mutual inductance between the coil array elements as disclosed in U.S. Pat. No. 5,804,969. In general, these techniques can be used to decouple adjacent and non-adjacent loop as well as transmission line elements. They can be used in receive arrays (with low-input impedance preamplifiers), in transmit arrays as well as in transceive arrays. These techniques can be also combined with loop over-lapping techniques to decouple non-adjacent loop elements. Some of these variations and combinations were suggested over the past years to improve upon or extend the capabilities of the underlying decoupling techniques; for instance see U.S. Patent Applications No. 2006/0006870 and 2009/0289630, and U.S. Pat. Nos. 6,927,575; 7,091,721; and 8,193,812.

Unfortunately, passive decoupling requires accurate determination of the decoupling inductor or capacitor values which change as function of the load (i.e., subject under examination). Additionally, for array of large number of channels, determining the capacitors and/or inductors values becomes cumbersome and iterative in nature, rendering overall RF coil development and debugging rather time- and cost-consuming. Furthermore, capacitors and inductors have finite loss associated with them, and hence, using excess of these elements to decouple the array elements increases the overall noise level. Other limitations include that, under some coil decoupling requirements, the capacitors and/or inductors values are non-feasible, or hard to integrate into coil structure. Finally, this method adds parasitic inductive and capacitive effects which cause un-desired resonances (due to the additional loops formed when adding the decoupling networks), this in turn brings about considerable difficulties in constructing RF coils with large channel counts or conformal 3D coils.

In 2N-port decoupling network methods, a 2N-port RF network is designed to decouple N-element receive array. The network which is composed of passive elements, e.g., capacitors, inductors and transmission lines, is placed between the N coils and the N preamplifiers. Taking into account the coupling matrix between the N elements, the decoupling network can be realized to decouple the coil elements. Such a technique was disclosed in U.S. Pat. No. 6,727,703. It is remarked here that this method can be applied in principle to transmit arrays as well.

Unfortunately, the 2N-port RF network method requires accurate determination of the array coupling matrix which changes as function of the load, i.e., human subject. Furthermore, the decoupling network is not always realizable especially for large number of array elements. The limitations of this method also include that the losses associated with decoupling matrix increases the overall all noise figure of each receive chain. Finally, with this method, preamplifier noise matching as required for optimized receive arras, is not always guaranteed.

Surrounding transmit array loop elements individually or in sub-groups inside a conductive shield as disclosed in U.S. Patent Application No. 2010/0164492 has proven efficient means to decouple RF array elements. This decoupling technique is based on blocking the interfering magnetic field flux between the elements.

Unfortunately, this method impairs individual coil transmit efficiency significantly. Furthermore, with this method, coil construction contains large amount of conductors on which eddy currents will be sustained and impair the imaging results, i.e., in EPI sequences

Using either Cartesian-feedback networks or multiple transmit channels with independent control over phase and magnitude, the coupling between element in the transmit arrays can be compensated. The methods disclosed in U.S. Pat. Nos. 7,336,074 and 7,692,427 are based generally on this approach.

Unfortunately, active decoupling through transmit channel phase and magnitude manipulation requires accurate determination of the array coupling matrix which changes as function of the load, i.e., human subject. Furthermore, Cartesian-feedback networks are inherently narrowband and consequently they limit the transmit RF pulse bandwidth (renders the method un-practical for many MRI applications). Finally, decoupling arrays with large number of elements is still a challenge with these methods (requires non-feasible hardware realizations)

Recognizing the limitations associated with each of the RF coil array elements decoupling techniques disclosed in the past, it remained for the present inventors to discover a decoupling method and array configuration to overcome the above noted limitations.

### SUMMARY OF THE INVENTION

The present invention overcomes the aforementioned drawbacks by providing a magnetic wall that cancels electromagnetic fields incident upon it by attenuating or redirecting those incident electromagnetic fields.

It is an aspect of the invention to provide a magnetic wall for decoupling radio frequency (“RF”) coils arranged in proximity to each other. The magnetic wall includes a plurality of resonators composed of a conductive material, each of the plurality of resonators being sized and shaped such that in the presence of an incident electromagnetic field the resonators generate an electromagnetic field that cancels the incident electromagnetic field. The magnetic wall also includes a substrate composed of an electrically insulating material, the substrate being configured to maintain the plurality of resonators in a spaced arrangement.

It is another aspect of the invention to provide an RF coil system that includes at least two RF coils arranged in proximity to each other and a magnetic wall positioned between the at least two RF coils. The magnetic wall includes a plurality of resonators composed of a conductive material, each of the plurality of resonators being sized and shaped such that when one of the at least two RF coils produces an electromagnetic field the plurality of resonators operate to cancel the electromagnetic field such that a current is not induced in the other of the at least two RF coils. The magnetic wall also includes a substrate composed of an electrically insulating material, the substrate being configured to maintain the plurality of resonators in a spaced arrangement.

The foregoing and other aspects and advantages of the invention will appear from the following description. In the description, reference is made to the accompanying drawings which form a part hereof, and in which there is shown by way of illustration a preferred embodiment of the invention. Such embodiment does not necessarily represent the full scope of the invention, however, and reference is made therefore to the claims and herein for interpreting the scope of the invention.

### BRIEF DESCRIPTION OF THE DRAWINGS

FIG. 1 is an example of a loop coil element;

FIG. 2 is a plot showing the reflection coefficient response of the coil element of FIG. 1;

FIG. 3A is an example of a radio frequency (“RF”) coil array that includes two loop coil elements;

FIG. 3B is an example of an RF coil array that includes two overlapped loop coil elements;

FIG. 4 is a plot showing the reflection coefficient response of one of the coil elements in the RF coil array of FIG. 3;

FIG. 5 is an illustration of the field lines corresponding to an example electromagnetic field generated by one of the coil elements in the RF coil array of FIG. 3;

FIG. 6 is a plot of the relative magnitude of the vector magnetic field density as a function of position along a line linking the coil elements in the RF coil array of FIG. 3A, in which an induced magnetic field is shown to be present in the coil element adjacent to the coil element producing an electromagnetic field;

FIG. 7A is an example of a magnetic wall for decoupling adjacent RF coil elements;

FIG. 7B is an example of a portion of a magnetic wall in which resonators are disposed on the surface of a substrate;

FIG. 7C is an example of a portion of a magnetic wall in which resonators are embedded, or otherwise disposed, within a substrate;

FIG. 8 is a plot of the real and imaginary parts of a complex relative permeability spectrum for an example magnetic wall;

FIG. 9 is an example of a square spiral resonator that may form a part of the magnetic wall;

FIG. 10 is an example of a magnetic wall for decoupling adjacent RF coil elements, in which the magnetic wall is composed of three layers of substrate and resonators;

FIGS. 11A and 11B illustrate an example of a magnetic wall being used to decouple two adjacent RF coil elements;

FIG. 11C illustrates an example of a magnetic wall being used to decouple two overlapped RF coil elements;

FIG. 12 is an illustration of the field lines corresponding to an example electromagnetic field generated by one of the coil elements in the RF coil array of FIG. 11A in the presence of a magnetic wall;

FIG. 13 is a plot of the relative magnitude of the vector magnetic field density as a function of position along a line linking the coil elements in the RF coil array of FIG. 11A, in which no magnetic field is induced in the coil element adjacent to the coil element producing an electromagnetic field;

FIGS. 14A and 14B illustrate a magnetic field incident on a volume of free space and a similar volume of magnetic wall;

FIG. 15 is a plot of reflection coefficients in an RF coil array with and without a magnetic wall;

FIG. 16 is a plot of transmission coefficients in an RF coil array with and without a magnetic wall;

FIG. 17A-C are examples of RF coil systems that include an array of RF coils and one or more magnetic walls used to decouple the various RF coil elements in the array; and

FIG. 18 is a block diagram of an example of a magnetic resonance imaging (“MRI”) system that may employ the present invention.

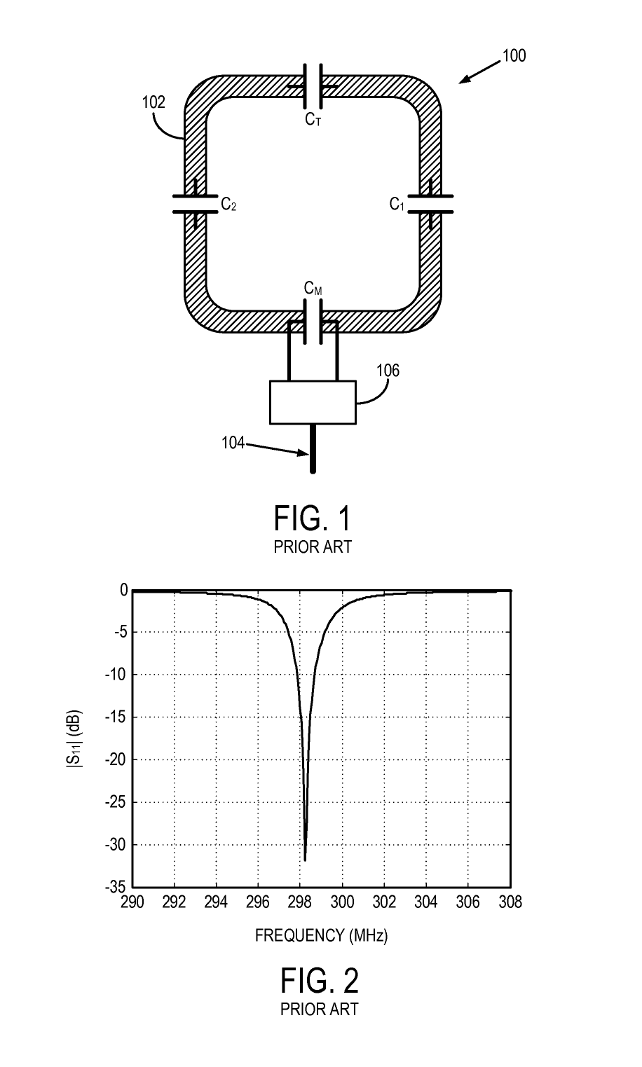

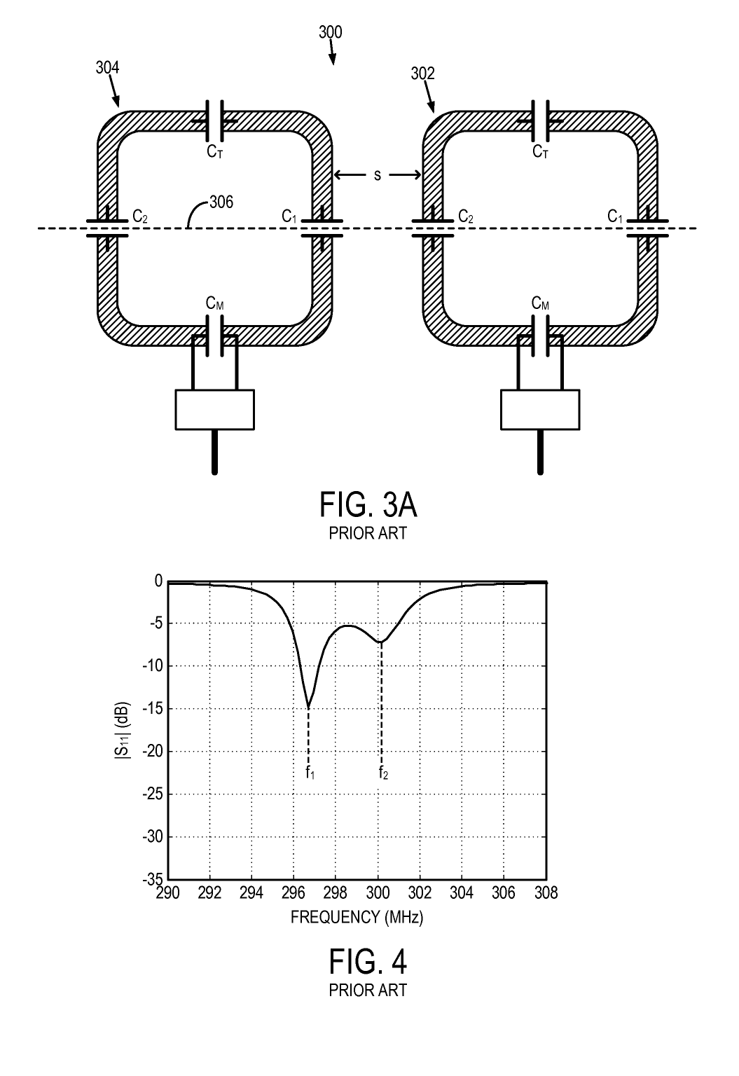

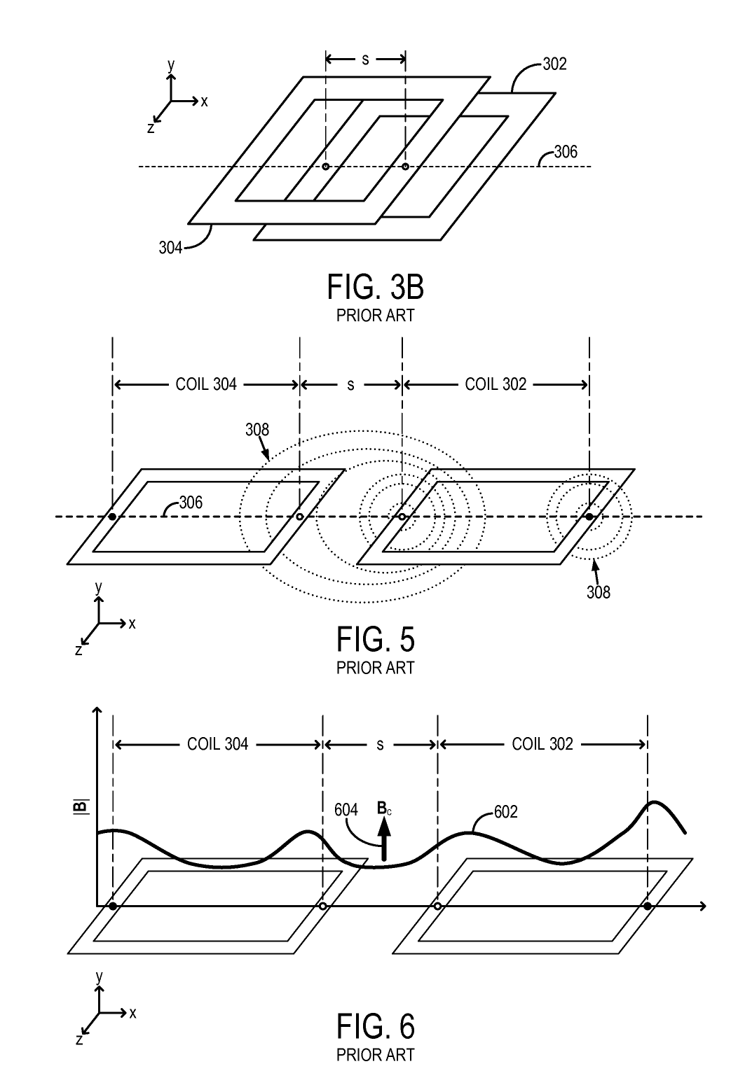

### DETAILED DESCRIPTION OF THE INVENTION

A system for decoupling radio frequency (“RF”) coil elements that form a part of an RF coil array used for magnetic resonance imaging (“MRI”) and a method for using such a system are provided. The system of the present invention includes a magnetic wall used to reduce the mutual coupling between coil elements in an RF coil array. The magnetic wall is inserted between the coil elements to suppress the magnetic field component responsible for the mutual coupling. The magnetic wall is modular, and multiple magnetic walls may be arranged to form an array depending on the number of coil elements in the RF coil array and their spatial arrangement. For overlapped coil elements, the magnetic wall can be in inserted in the overlap region to reduce the mutual coupling. In general, the magnetic wall may be configured to act as a magnetic field absorber, a magnetic field conductor, or as both. Once the magnetic field component responsible for the mutual coupling impinges upon the magnetic wall, the magnetic wall presents a large impedance to this magnetic field component, which prevents it from linking the neighboring coil elements.

The mechanism by which the magnetic wall isolates the coil elements depends on the design of the magnetic wall structure. The magnetic wall can be designed to absorb, or attenuate, the incident magnetic field; to sustain the incident magnetic field and redirect it somewhere other than the neighboring coils; or to sustain and absorb the incident magnetic field such that the field does not interfere with the neighboring coil elements. Physically, the absorption effect can result not only from a physical loss mechanism, but from field cancellation effects, which may generally be regarded as a loss.

The magnetic wall is designed to have complex relative permeability relative to air,

μᵣ=μᵣ′iμᵣ″ (1);

where the real part, λᵣ′, represents the ability of the magnetic wall structure to sustain, or store, the incident magnetic field; and the imaginary part, μᵣ″, represents the ability of the magnetic wall structure to attenuate the incident field. For decoupling purposes, an absorptive magnetic wall is designed with large and negative imaginary permeability part, μᵣ″<<0; a directive magnetic wall, is designed with large positive real permeability part, μᵣ′>>1; and a directive and absorptive magnetic wall is designed such that μᵣ′>>1 and μᵣ″<<0 are achieved simultaneously. As noted above, μᵣ″<<0 does not necessarily mean a physical loss mechanism; rather, field cancelation—i.e., magnetic resonances—can result in μᵣ″<<0 in narrowband magnetic wall structures. The latter loss mechanism is preferable for an RF coil array design because it does not reduce SNR.

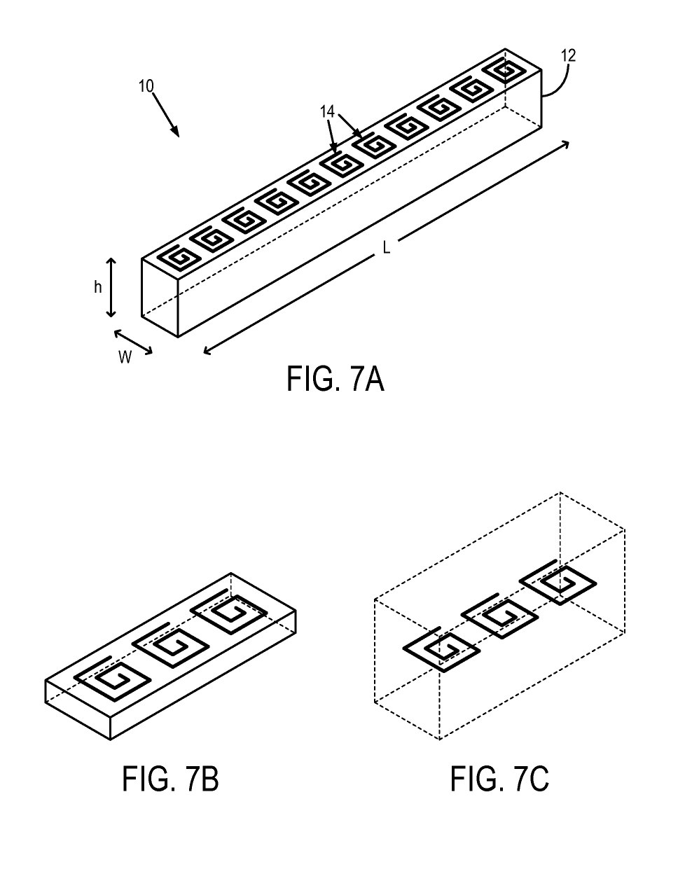

An example of a magnetic wall is illustrated in FIG. 7A. The magnetic wall 10 includes a substrate 12 which maintains a plurality of resonators 14 in a spaced arrangement, or relationship, with one another. The resonators 14 may be disposed on the surface of the substrate 12, as illustrated in FIG. 7B, may be disposed or embedded within the substrate 12, as illustrated in FIG. 7C, or combinations of both. The resonators 14 may be spaced in a regular or irregular arrangement. As one example, the resonators 14 may be uniformly spaced on or within the substrate 12. As another example, the resonators 14 may be nonuniformly spaced apart on or within the substrate 12. As yet another example, the resonators 14 may be randomly or pseudorandomly spaced on or within the substrate 12. By way of example, when the resonators 14 are embedded, or otherwise disposed, within the substrate 12, the resonators 14 may be arranged such that they are all coplanar or such that they form various layers of coplanar arrangements. It will be appreciated, however, that the resonators 14 need not necessarily be arranged uniformly in three-dimensional space.

The substrate 12 may be composed of a dielectric material or a combination of such materials, and may be sized as a thin layer of material or as a bulk of material. In some configurations, the substrate 12 may be composed of a printed circuit board (“PCB”) material upon which the resonators 14 are disposed. In other configurations, the substrate 12 may be composed of a dielectric host material within which the resonators 14 are embedded or otherwise disposed. As will be described below in more detail, the magnetic wall 10 may include a single substrate 12 layer, or may be composed of multiple substrate 12 layers arranged on top of each other, with each substrate 12 layer having its own set of resonators 14 arranged thereon.

In general, the resonators 14 are constructed with certain shapes using conductive traces or wires. The resonators 14 are preferably designed such that their largest dimension is very small compared to the operating wavelength of the RF coil array in which the magnetic wall 10 will be used. Resonance in the magnetic wall 10 is achieved by virtue of the distributed capacitance in the resonators 14 and the inductance of the forming conductors of the resonators 14. When the size of the resonators 14 as well as their interspacing within the substrate 12 is much smaller that the RF wavelength, the magnetic wall 10 exhibits magnetic resonance at a resonance frequency, f_{MW}. It is important to note that the magnetic wall 10 resonance frequency, f_{MW}, is not the same as the Larmor frequency used for MRI. Because these frequencies are different, two unique decoupling features of the magnetic wall 10 are implicated. First, the magnetic wall 10 does not interfere with magnetic resonance signals, whether the RF coil array is operating in a transmit mode or a receive mode. Second, the decoupling achieved by the magnetic wall 10 is intrinsically load invariant. That is, the decoupling does not require readjustment or retuning when the load changes. By way of example, the magnetic wall 10 may be designed such that its resonance frequency, f_{MW}, is equal to the higher coupled-mode frequency, f₂, so as to minimize the coupling between coil array elements.

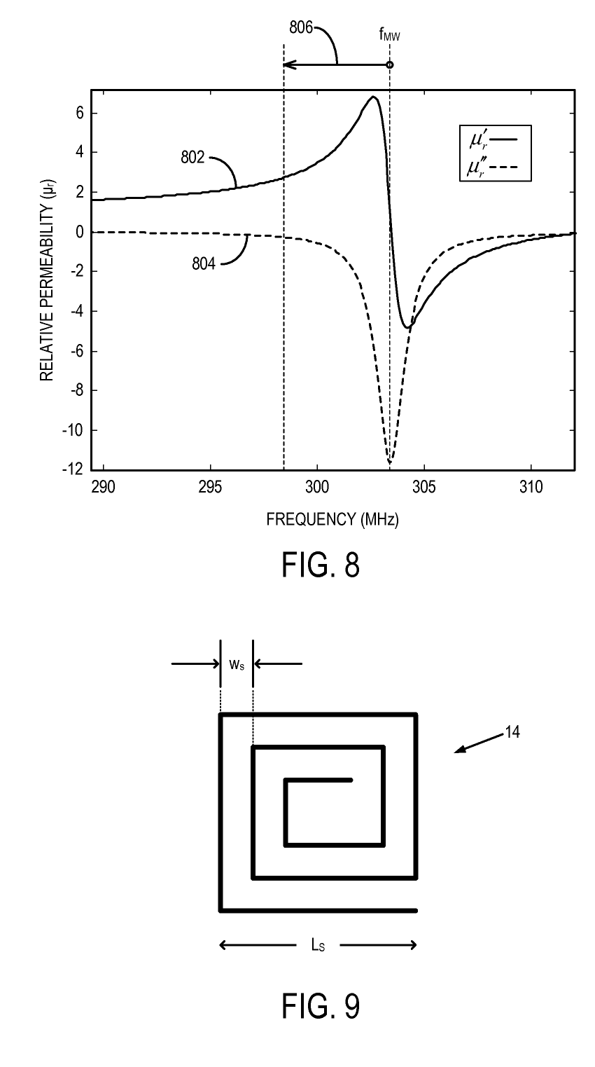

An example of the effective magnetic permeability of the magnetic wall 10 as a function of frequency is illustrated in FIG. 8. The real part of the effective permeability, indicated by solid line 802, is negative at frequencies greater than the resonance frequency, f_{MW}, and positive at frequencies below the resonance frequency, f_{MW}. The imaginary part of the effective permeability, indicated by dashed line 804, is negative and large in a small bandwidth around the resonance frequency, f_{MW}. The permeability values in spectral band identified by arrow 806 are sufficient to provide the decoupling effect.

The value of the real and imaginary parts μᵣ′ 802 μᵣ″ 804, respectively, of effective permeability, μᵣ, of the magnetic wall 10 can be controlled in general by the number of resonators 14 per unit volume. Specifically, the effective permeability can be controlled by adjusting the number of resonators 14 in the direction of the applied magnetic field, their relative spacing in that direction, and the shape of the resonators 14. For narrow-band magnetic wall designs, operating at frequencies in the spectral band 806 can yield at least the following designs. When the operating frequency is slightly less than the resonance frequency, f_{MW}, μᵣ″ will be negative and large while μᵣ′ will be positive and relatively small. Hence, operating at frequencies near to but smaller than the resonance frequency, f_{MW}, of the magnetic wall 10 yields an absorptive wall. When the operating frequency is around the middle of the spectral band 806, then μᵣ″ will be negative and relatively large and μᵣ′, will be positive and large. Hence, operating at frequencies near the middle of the spectral band 806 yields a magnetic wall 10 that is both absorptive and directive. When the operating frequency is close to the lower frequency end of the spectral band 806, then μ″ᵣ will be negative and relatively small while μᵣ′ will be positive and relatively large. Hence, operating at frequencies near the lower end of the spectral band 808 yields a magnetic wall 10 that is directive. Operating at the resonance frequency, f_{MW}, of the magnetic wall 10 is preferably avoided because doing so will result in the magnetic wall 10 interacting with the coil elements of the RF coil array. Hence, as a general design guideline, the magnetic wall 10 is designed such that its resonance frequency is greater than the Larmor frequency corresponding to nuclear spin species of interest by at least one-half of the transmitted/received signal bandwidth.

Various resonators 14 can be used to construct a magnetic wall 10 with the desired permeability properties mentioned above. Examples of resonators 14 include circular or square split ring resonators (“SRR”), circular or square spiral resonators (“SR”), and Fractal Hilbert curves. Selecting the particular design for the resonators 14 depends on the bandwidth, miniaturization requirements, manufacturability, and desired permeability. By way of example, for RF coil arrays designed for MRI, it is desirable for the coil elements to be densely packed around the region-of-interest to be imaged; thus, a high miniaturization rate is desired for the magnetic wall 10. Furthermore, MRI excitation and detection is essentially narrowband. Because of these design considerations, a spiral resonator may be advantageous because this design offers significant miniaturization rate (a resonator dimension on the order of 0.01·λ is achievable) and a high Q-factor. Without loss of generality, an example of such a resonator is an N-turn square spiral resonator, such as the one illustrated in FIG. 9. Such N-turn square spiral resonators may be defined by their spiral side length, Lₛ, and the spacing between spiral conductors, wₛ. It will be appreciated, however, that other resonator types can be used to achieve the decoupling effects of the magnetic wall 10, as well. With spiral resonators affixed to the substrate 12, the magnetic wall 10 is responsive to magnetic fields that are locally orthogonal to the plane of the spiral resonator. Miniaturization of the magnetic wall 10 can be accomplished following well-known approaches, such as utilizing high permittivity substrate 12 materials and optimizing the resonator 14 inductance/capacitance—such as by changing the number of turns in the resonator 14—to achieve the desired magnetic wall 10 resonance frequency.

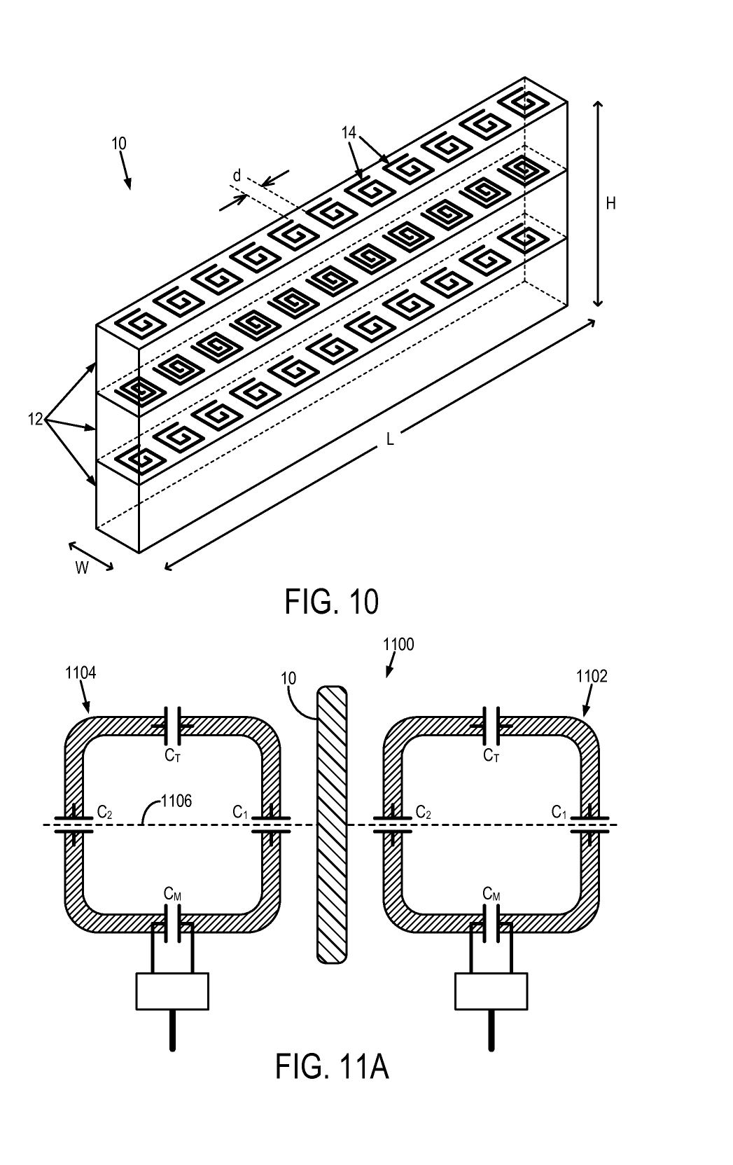

By way of example, and referring now to FIG. 10, a magnetic wall 10 composed of three substrate 12 layers and three sets of resonators 14 is illustrated. This magnetic wall 10 is configured to operate as both and absorptive and directive magnetic wall. The substrate 12 layers may be composed of printed circuit board (“PCB”) material, such as Rogers 4350B PCB material (Rogers Corporation; Chandler, Ariz.). On each substrate 12 layer, an array of twelve resonators 14 is affixed. For example, the resonators 14 are spiral resonators that are printed on the PCB substrate 12.

Example dimensions of the magnetic wall 10 illustrated in FIG. 10 may be as follows. The thickness of each substrate 12 layer may be 0.061 inches. The spacing, d, between resonators 14 may be 0.062 inches. The spiral resonators may be made of copper strips having a thickness of 0.0014 inches and a width of 0.005 inches. The spiral side length, Lₛ, may be 0.275 inches and the spacing between spiral conductors, wₛ, may be 0.005 inches. The side width of the magnetic wall, W, may be 0.3125 inches, the total length, L, of the magnetic wall may be 4.30 inches, and the total height, H, of the magnetic wall 10 may be 0.187 inches.

In configurations of the magnetic wall 10 that make use of multiple substrate 12 layers, it is noted that the resonators 14 can be differently designed and arranged on different substrate 12 layers. For instance, in the arrangement illustrated in FIG. 10, the middle substrate 12 layer may be designed with 10-turn spiral resonators, while the other two substrate 12 layers may be designed with 8-turn spiral resonators. Such an arrangement may enhance the decoupling effect of the magnetic wall 10.

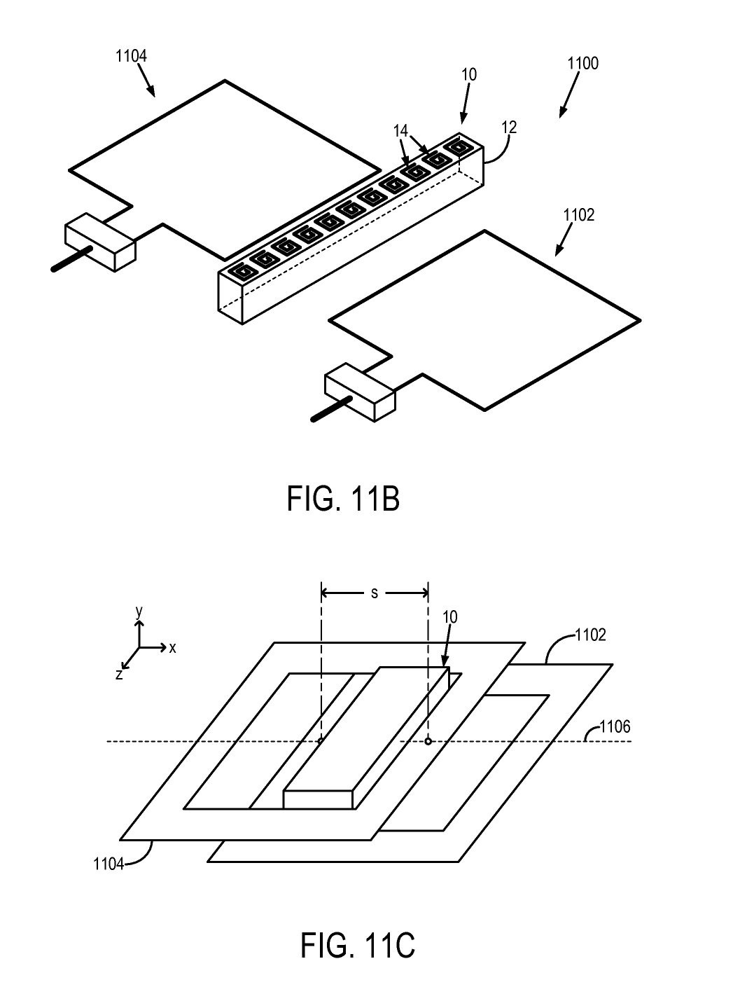

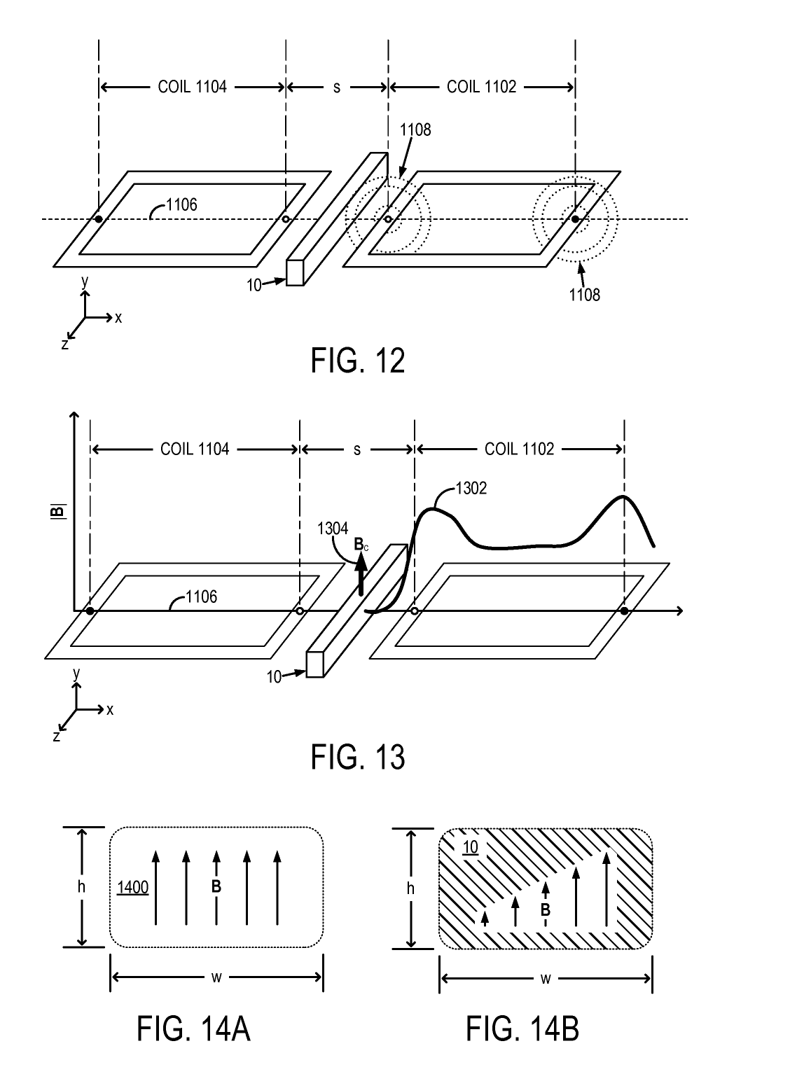

Referring now to FIGS. 11A and 11B, an example of an RF coil array 1100 that includes two coil elements 1102, 1104 and a magnetic wall 10 is illustrated. In this configuration, the electromagnetic coupling between the coil elements 1102, 1104 is significantly eliminated by way of the magnetic wall 10. This effect is illustrated in FIGS. 12 and 13. FIG. 12 illustrates the effect of placing the magnetic wall 10 between the coil elements 1102, 1104 on the magnetic flux lines 1108 that exist when coil element 1102 is driven by a current and coil element 1104 is properly terminated. Compared to the magnetic flux lines illustrated in FIG. 5, it can be seen that when the magnetic wall 10 is present between the coil elements 1102, 1104, the excited coil element 1102 behaves in isolation from the second coil element 1104. That is, the coil elements 1102, 1104 are decoupled. The decoupling effect of the magnetic wall 10 is reciprocal. FIG. 13 illustrates the relative magnitude of the vector magnetic field density, |B|, along the line 1106 linking coil elements 1102 and 1104. As depicted in FIG. 13, the distribution of the magnetic loops becomes similar to the typical distribution of a single loop working in isolation, as desired. Consequently, the decoupling effect is confirmed by the reflection coefficient spectrum, which is similar to the one illustrated in FIG. 2. When the coil elements 1102, 1104 are overlapping, the magnetic wall 10 can be inserted in the overlapping area as illustrated in FIG. 11C. The effect of positioning the magnetic wall 10 in the overlapping space is similar to positioning the magnetic wall 10 between two non-overlapping coil elements; that is, the two coil elements 1102, 1104 are decoupled.

To further explain the operation of the magnetic wall 10, consider FIGS. 14A and 14B. FIG. 14A shows a magnetic field oriented upward in space and incident (from one side) on a free-space, such as, air-filled, volume 1400. The cross section of the volume 1400 is of width, w, and thickness, h. The vector magnetic field, B, inside the volume 1400 is annotated showing that the field goes from one side to the other without change. When the volume 1400 is filled with a magnetic wall 10 material, as shown in FIG. 14B, the incident magnetic field is contained inside the magnetic wall 10 and does not pass to the other end. Hence, when such a magnetic wall 10 is placed in-between or surrounding coil array elements, it effectively decouples the coil elements.

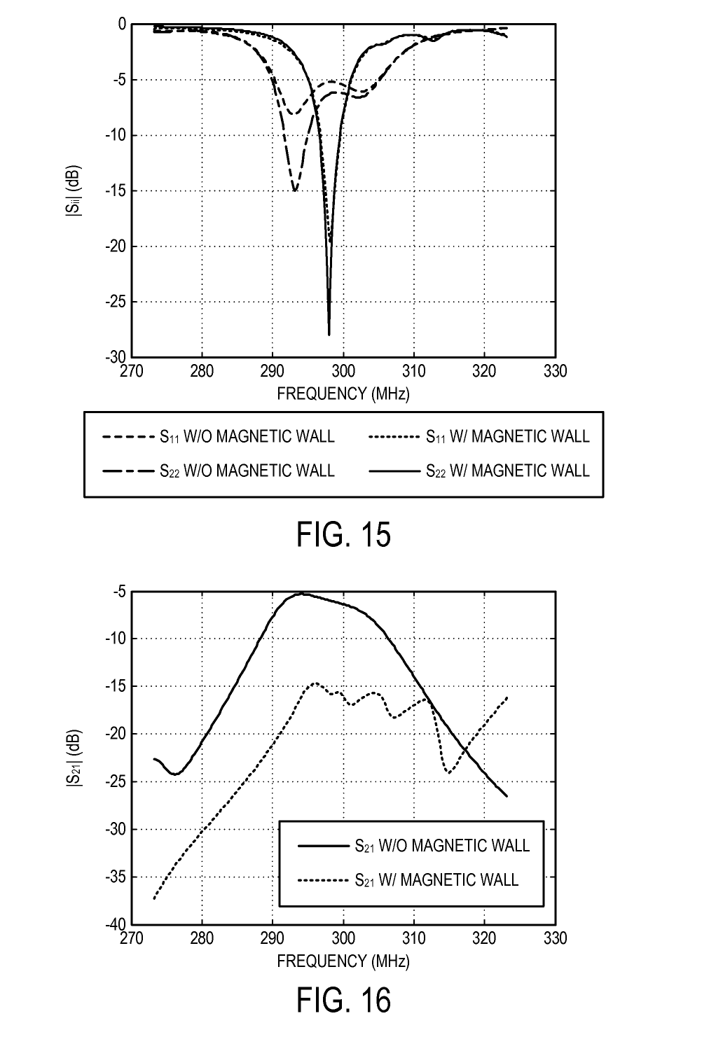

Without the magnetic wall 10, the measured reflection response of the coil elements indicates strong coupling between the coil elements. This coupling is manifested in loss of match/tune and in mode splitting, as shown in FIG. 15. Strong coupling is also evident in the transmission coefficient measurements obtained without the magnetic wall 10, as shown in FIG. 16. In particular, as shown in FIG. 16, without the magnetic wall 10, mode splitting is also evident in the S₂₁ spectrum, in which the value of transmission is high at the desired operation frequency. On the other hand, a significant improvement is obtained when the designed magnetic wall 10 is utilized, as demonstrated in FIGS. 15 and 16. First, the magnetic wall 10 decouples the coil elements effectively, as highlighted by the single resonance in the S₁₁ and S₂₂ spectra illustrated in FIG. 15. This shows that there is no mode splitting and that the response resemble isolated coil elements. Second, the magnetic wall 10 effectively reduces the transmission coefficient between the coil elements, as illustrated in FIG. 16. With the magnetic wall 10 present, the transmission coefficient, S₂₁, drops from −5 dB to −15 dB, suggesting a very small coupling between the coil elements.

The sensitivity of coil elements separated by a magnetic wall 10 can be evaluated by measuring the unloaded-to-loaded Q-factor and computing the ratio between them. For both coil elements, the measured unloaded-to-loaded Q-ratio is almost the same with and without the magnetic wall 10. This result confirms that the magnetic wall 10 provides an almost lossless decoupling mechanism and that the attenuation in the magnetic wall 10 is due to field cancelation. The magnetic wall 10 does not interfere, block, or comprise magnetic resonance signals.

In one configuration suitable for imaging at 3T, decoupling may be minimized to values less than −20 dB by fine-tuning the magnetic wall 10 such that its fundamental resonance frequency equals to the higher coupled-mode frequency. This may be accomplished by off-setting at least one layer of resonators 14 with respect to the other.

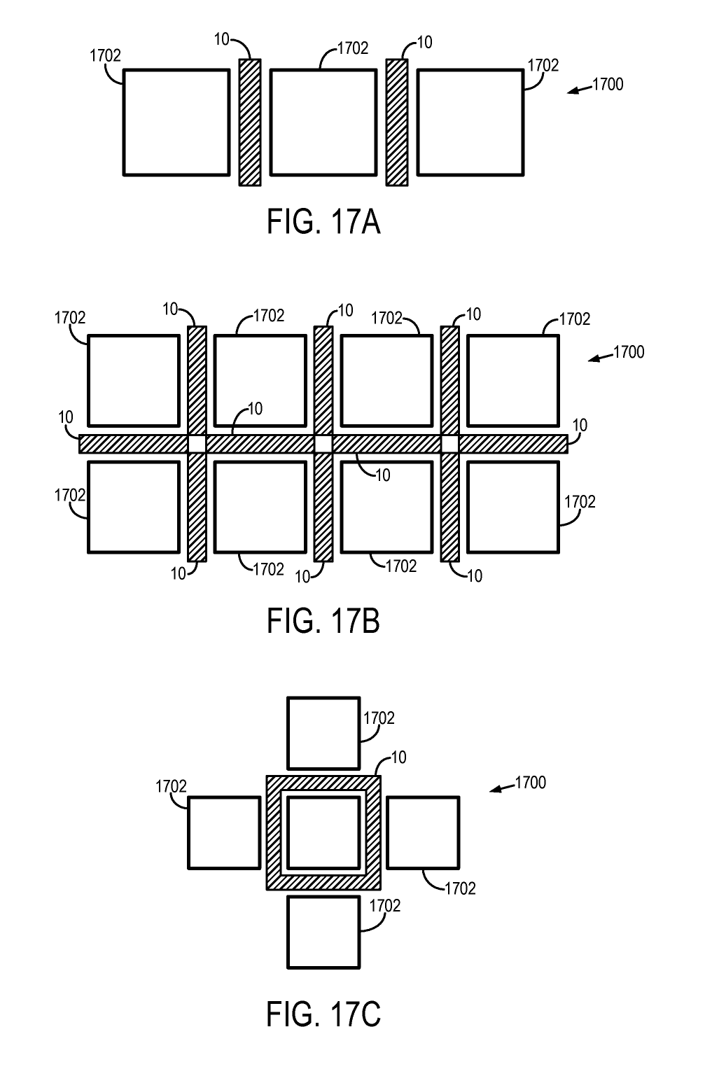

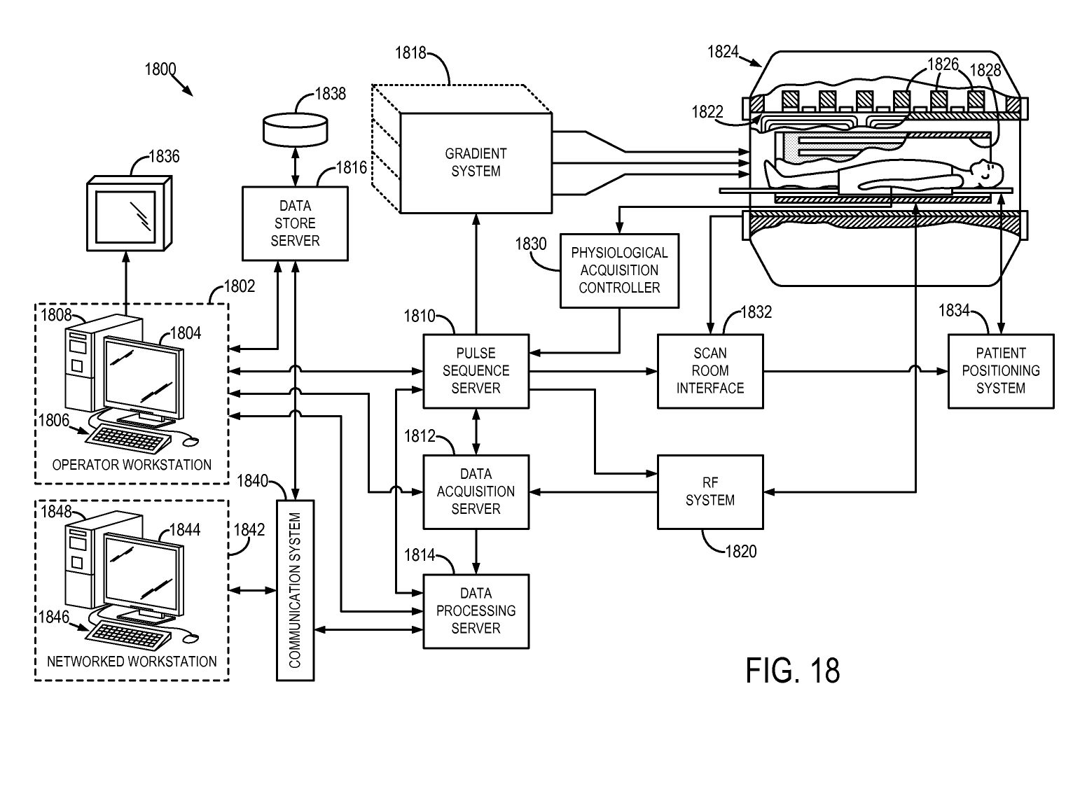

The disclosed magnetic wall 10 can be applied for RF coil arrays with a large number of coil elements because the underlying electromagnetic coupling mechanism is the same. The magnetic walls 10 can be placed to surround or enclose the coil elements from all directions, and additional coil elements can be added modularly to realize large arrays. The magnetic wall 10 of the present invention places no restriction on the shape or geometry of the RF coil array. In general, the magnetic wall 10 of the present invention is capable of decoupling coil elements arranged over the spatial extent of line, whether the line is straight, circular, or arbitrarily shaped. The magnetic wall 10 of the present invention is also capable of decoupling coil elements arranged over a plane, whether the plane is planar, cylindrical, spherical, conformal, or otherwise arbitrarily shaped. The magnetic wall 10 can be implemented using rigid or flexible array formers, which might be continuous or have detached portions. In general, the placement of the resonators 14, their type, shape, number, periodicity, and orientation in three dimensions can be varied over the spatial extent of the magnetic wall 10. It is understood that three-dimensional and conformal arrays with or without detachable parts can be easily constructed. A few examples of the magnetic wall 10 being used to decouple an RF coil array 1700 that includes a plurality of RF coils 1702 are illustrated in FIGS. 17A-17C.

The magnetic wall 10 of the present invention can be used to construct optimized RF coil arrays in a number of different ways. For instance, the magnetic wall 10 can be manufactured as tiles and inserted modularly where needed between the coil array elements. In another configuration, the coil array elements, as well as the magnetic wall 10, can be manufactured on the same substrate during the same manufacturing process. Subsequently, the RF coil array and magnetic wall 10 can be conformed over a desired former to cover the region-of-interest. It is contemplated that the substrate 12 can be made of flexible material, such as flexible printed circuit boards, or of semi-rigid materials, such as semi-rigid printed circuit boards. It is also noted that the magnetic wall 10 of the present invention may be used to complement and enhance existing decoupling strategies.

Referring particularly now to FIG. 18, an example of a magnetic resonance imaging (“MRI”) system 1800 is illustrated. The MRI system 1800 includes an operator workstation 1802, which will typically include a display 1804; one or more input devices 1806, such as a keyboard and mouse; and a processor 1808. The processor 1808 may include a commercially available programmable machine running a commercially available operating system. The operator workstation 1802 provides the operator interface that enables scan prescriptions to be entered into the MRI system 1800. In general, the operator workstation 1802 may be coupled to four servers: a pulse sequence server 1810; a data acquisition server 1812; a data processing server 1814; and a data store server 1816. The operator workstation 1802 and each server 1810, 1812, 1814, and 1816 are connected to communicate with each other. For example, the servers 1810, 1812, 1814, and 1816 may be connected via a communication system 1840, which may include any suitable network connection, whether wired, wireless, or a combination of both. As an example, the communication system 1840 may include both proprietary or dedicated networks, as well as open networks, such as the internet.

The pulse sequence server 1810 functions in response to instructions downloaded from the operator workstation 1802 to operate a gradient system 1818 and a radiofrequency (“RF”) system 1820. Gradient waveforms necessary to perform the prescribed scan are produced and applied to the gradient system 1818, which excites gradient coils in an assembly 1822 to produce the magnetic field gradients Gₓ, G_{y}, and G_{z} used for position encoding magnetic resonance signals. The gradient coil assembly 1822 forms part of a magnet assembly 1824 that includes a polarizing magnet 1826 and a whole-body RF coil 1828.

RF waveforms are applied by the RF system 1820 to the RF coil 1828, or a separate local coil (not shown in FIG. 18), in order to perform the prescribed magnetic resonance pulse sequence. Responsive magnetic resonance signals detected by the RF coil 1828, or a separate local coil (not shown in FIG. 18), are received by the RF system 1820, where they are amplified, demodulated, filtered, and digitized under direction of commands produced by the pulse sequence server 1810. The RF system 1820 includes an RF transmitter for producing a wide variety of RF pulses used in MRI pulse sequences. The RF transmitter is responsive to the scan prescription and direction from the pulse sequence server 1810 to produce RF pulses of the desired frequency, phase, and pulse amplitude waveform. The generated RF pulses may be applied to the whole-body RF coil 1828 or to one or more local coils or coil arrays (not shown in FIG. 18).

The RF system 1820 also includes one or more RF receiver channels. Each RF receiver channel includes an RF preamplifier that amplifies the magnetic resonance signal received by the coil 1828 to which it is connected, and a detector that detects and digitizes the I and Q quadrature components of the received magnetic resonance signal. The magnitude of the received magnetic resonance signal may, therefore, be determined at any sampled point by the square root of the sum of the squares of the I and Q components:

M=\sqrt{I²+Q²} (2);

and the phase of the received magnetic resonance signal may also be determined according to the following relationship:

$$ϕ = {tan}^{- 1} ( \frac{Q}{I} ) . \qquad ( 3 )$$

The pulse sequence server 1810 also optionally receives patient data from a physiological acquisition controller 1830. By way of example, the physiological acquisition controller 1830 may receive signals from a number of different sensors connected to the patient, such as electrocardiograph (“ECG”) signals from electrodes, or respiratory signals from a respiratory bellows or other respiratory monitoring device. Such signals are typically used by the pulse sequence server 1810 to synchronize, or “gate,” the performance of the scan with the subject's heart beat or respiration.

The pulse sequence server 1810 also connects to a scan room interface circuit 1832 that receives signals from various sensors associated with the condition of the patient and the magnet system. It is also through the scan room interface circuit 1832 that a patient positioning system 1834 receives commands to move the patient to desired positions during the scan.

The digitized magnetic resonance signal samples produced by the RF system 1820 are received by the data acquisition server 1812. The data acquisition server 1812 operates in response to instructions downloaded from the operator workstation 1802 to receive the real-time magnetic resonance data and provide buffer storage, such that no data is lost by data overrun. In some scans, the data acquisition server 1812 does little more than pass the acquired magnetic resonance data to the data processor server 1814. However, in scans that require information derived from acquired magnetic resonance data to control the further performance of the scan, the data acquisition server 1812 is programmed to produce such information and convey it to the pulse sequence server 1810. For example, during prescans, magnetic resonance data is acquired and used to calibrate the pulse sequence performed by the pulse sequence server 1810. As another example, navigator signals may be acquired and used to adjust the operating parameters of the RF system 1820 or the gradient system 1818, or to control the view order in which k-space is sampled. In still another example, the data acquisition server 1812 may also be employed to process magnetic resonance signals used to detect the arrival of a contrast agent in a magnetic resonance angiography (“MRA”) scan. By way of example, the data acquisition server 1812 acquires magnetic resonance data and processes it in real-time to produce information that is used to control the scan.

The data processing server 1814 receives magnetic resonance data from the data acquisition server 1812 and processes it in accordance with instructions downloaded from the operator workstation 1802. Such processing may, for example, include one or more of the following: reconstructing two-dimensional or three-dimensional images by performing a Fourier transformation of raw k-space data; performing other image reconstruction algorithms, such as iterative or backprojection reconstruction algorithms; applying filters to raw k-space data or to reconstructed images; generating functional magnetic resonance images; calculating motion or flow images; and so on.

Images reconstructed by the data processing server 1814 are conveyed back to the operator workstation 1802 where they are stored. Real-time images are stored in a data base memory cache (not shown in FIG. 18), from which they may be output to operator display 1812 or a display 1836 that is located near the magnet assembly 1824 for use by attending physicians. Batch mode images or selected real time images are stored in a host database on disc storage 1838. When such images have been reconstructed and transferred to storage, the data processing server 1814 notifies the data store server 1816 on the operator workstation 1802. The operator workstation 1802 may be used by an operator to archive the images, produce films, or send the images via a network to other facilities.

The MRI system 1800 may also include one or more networked workstations 1842. By way of example, a networked workstation 1842 may include a display 1844; one or more input devices 1846, such as a keyboard and mouse; and a processor 1848. The networked workstation 1842 may be located within the same facility as the operator workstation 1802, or in a different facility, such as a different healthcare institution or clinic.

The networked workstation 1842, whether within the same facility or in a different facility as the operator workstation 1802, may gain remote access to the data processing server 1814 or data store server 1816 via the communication system 1840. Accordingly, multiple networked workstations 1842 may have access to the data processing server 1814 and the data store server 1816. In this manner, magnetic resonance data, reconstructed images, or other data may exchanged between the data processing server 1814 or the data store server 1816 and the networked workstations 1842, such that the data or images may be remotely processed by a networked workstation 1842. This data may be exchanged in any suitable format, such as in accordance with the transmission control protocol (“TCP”), the internet protocol (“IP”), or other known or suitable protocols.

While certain embodiments of the present invention are discussed above, it should be appreciated by those skilled in the art that these embodiments are provided as illustrative examples and that these designs and configurations can be readily altered to maintain the same absorptive and/or directive properties of the magnetic wall to decouple any number of coil array elements in any number of different shapes or geometries. Thus, although the present invention has been described in terms of one or more preferred embodiments, it should be appreciated that many equivalents, alternatives, variations, and modifications, aside from those expressly stated, are possible and within the scope of the invention.

1. A magnetic wall for decoupling radio frequency (RF) coils arranged in proximity to each other, comprising:
a plurality of resonators composed of a conductive material, each of the plurality of resonators being sized and shaped such that in the presence of an incident electromagnetic field the resonators generate an electromagnetic field that cancels the incident electromagnetic field; and
a substrate composed of an electrically insulating material, the substrate being configured to maintain the plurality of resonators in a spaced arrangement.

2. The magnetic wall as recited in claim 1 in which the substrate is composed of a dielectric material.

3. The magnetic wall as recited in claim 1 in which the plurality of resonators are disposed on a surface of the substrate.

4. The magnetic wall as recited in claim 1 in which the plurality of resonators are embedded within the substrate.

5. The magnetic wall as recited in claim 1 in which the substrate is at least one of a flexible substrate, a semi-rigid substrate, and a rigid substrate.

6. The magnetic wall as recited in claim 1 in which the size and shape of the resonators are selected to result in a complex magnetic permeability having a positive real part and a negative imaginary part.

7. The magnetic wall as recited in claim 6 in which the number of the plurality of resonators is selected to result in a complex magnetic permeability having a positive real part and a negative imaginary part.

8. The magnetic wall as recited in claim 1 in which at least some of the resonators have a different resonance frequency than others of the resonators.

9. The magnetic wall as recited in claim 1 in which the resonators are sized and shaped to define a resonance frequency of the magnetic wall that is equal to a coupled mode frequency of the RF coils.

10. The magnetic wall as recited in claim 9 in which a location and orientation of each of the plurality of resonators is selected to define the resonance frequency.

11. The magnetic wall as recited in claim 1 in which the substrate is a layered substrate that includes at least one layer.

12. The magnetic wall as recited in claim 11 in which the layered substrate includes at least two layers and the plurality of resonators are arranged on a surface of each of the at least two layers.

13. The magnetic wall as recited in claim 12 in which a different number of resonators are arranged on different ones of the at least two layers.

14. The magnetic wall as recited in claim 1 in which the resonators are shaped as at least one of a split-ring resonator, a spiral resonator, and a fractal Hilbert curve.

15. The magnetic wall as recited in claim 14 in which the split-ring resonator is at least one of a square split-ring resonator and a circular split-ring resonator.

16. The magnetic wall as recited in claim 14 in which the spiral resonator is at least one of a square spiral resonator and a circular spiral resonator.

17. The magnetic wall as recited in claim 1 in which the plurality of resonators are sized and shaped such that in the presence of an incident electromagnetic field, the resonators generate an electromagnetic field that cancels the incident electromagnetic field by at least one of attenuating the incident magnetic field, redirecting the incident magnetic field, or a combination thereof.

18. The magnetic wall as recited in claim 1 in which the plurality of resonators are maintained in at least one of a regular and irregular spaced arrangement.

19. A radio frequency (RF) coil system, comprising:
at least two RF coils arranged in proximity to each other;
a magnetic wall positioned between the at least two RF coils, the magnetic wall comprising:
a plurality of resonators composed of a conductive material, each of the plurality of resonators being sized and shaped such that when one of the at least two RF coils produces an electromagnetic field the plurality of resonators operate to cancel the electromagnetic field such that a current is not induced in the other of the at least two RF coils; and
a substrate composed of an electrically insulating material, the substrate being configured to maintain the plurality of resonators in a spaced arrangement.

20. The RF coil system as recited in claim 19 in which the substrate is composed of a dielectric material.

21. The RF coil system as recited in claim 19 in which the resonators are sized, shaped, and arranged such that the magnetic wall has a complex magnetic permeability having a positive real part and a negative imaginary part.

22. The RF coil system as recited in claim 19 in which the resonators are sized, shaped, and arranged to define a resonance frequency of the magnetic wall that is equal to a coupled mode frequency of the at least two RF coils.

23. The RF coil system as recited in claim 19 in which the magnetic wall comprises a plurality of magnetic walls, each magnetic wall being sized and shaped such that one of the magnetic walls is positioned between each adjacent pair of the at least two RF coils.

24. The RF coil system as recited in claim 19 in which the magnetic wall comprises a plurality of magnetic walls, each of the plurality of magnetic walls having a different resonance frequency.

25. The RF coil system as recited in claim 19 in which the at least two RF coils are arranged such that at least two RF coils are partially overlapping each other.
